(19) United States
(12) Patent Application Publication
(10) Pub. No.: US 2010/0072753 A1
(43) Pub. Date: Mar. 25, 2010

(54) Harvesting alternative energy/power by combining, adding, reshaping, modifying, rethinking and/or blending of all possible energy /power output devices within the same spatial area, thereby reducing our energy/power dependence on the world's natural resources such as oil, coal and natural gas

(76) Inventor: Edgar B. Bell, Thornton, CO (US)

Correspondence Address: Edgar B. Bell, 11760 Garfield St., Thornton, CO, 80233, US

(21) Appl. No.: 12/322,530

(22) Filed: Feb. 4, 2009

Related U.S. Application Data
(60) Provisional application No. 61/192,746, filed on Sep. 23, 2008.

(51) Int. Cl. F03B 13/00; F03D 9/00; H01L 31/00; F03G 7/00

(52) U.S. Cl. 290/54; 136/243; 60/641.2

(57) ABSTRACT

Adapting alternative energies in different and possibly new ways to reduce our dependence on natural fuels such as oil, gas, and coal; thereby possibly and probably reducing our carbon footprint, terrorism, long and expensive supply lines of oil tankers, pipelines, and updated electric lines; and all the while, still supplying and even adding more power to our nation's energy system.

### BACKGROUND

For more than several years I've wondered about the energy crisis. A couple of years ago a friend and I stopped at an Indian casino where they had a wind turbine generating electricity for the casino, but this generated only X % of the power needed. About a year after we visited the casino, I finally came up with a solution. Then, I started thinking about all the other possibilities for harvesting of alternative energies. This will help supplant the natural fuels we may possess but, yet, are so limited by. Any individual and/or business, which have a battery, solar, and/or electric powered automobile or another type of a vehicle, a structure and/or land, could use the ideas of this patent. Any municipality, PUC, water board, local, state and/or federal government, that have roads, bridges, overpasses, buildings, open areas, rivers, hydroelectric facilities, could also use one or more ideas of this patent. If we can set our priorities to invest in capturing all the free things, such as the wind, solar, geothermal, water power, etc. before we start paying for energy at the pump, we'll save a lot of money and natural resources in the process. All of these different technologies are fine by themselves, but when they are blended and/or combined with each other, they would add extra electrical benefits.

A wind turbine produces electrical power, but if there were no wind, there would be no electrical power generated. This is the same for any and all “wind farms”. If solar (photovoltaic) cells were added to this tower, any sunlight would also dramatically increase the electrical output through this process. These pliable (?) solar cells could be attached to the tower structure itself and the electricity could flow directly to the substation of the wind turbine. Also, I don't see any reason why there can't be other solar cell collectors within the “wind farm” area, which will further enhance the electrical production.

This same idea of blending technologies could be applied in reverse, by adding wind-generating capabilities to solar collectors and/or “solar farms”. This could include houses or other buildings, etc. where the wind turbines are built behind the solar panels. These “farms” could also employ rigid but collapsible wind turbines and integrate the technologies to find the solution to use at a given period of time. During periods of darkness, maybe other types of wind collectors could be extended for more efficient collecting possibilities.

The idea is to increase the electrical output of a myriad of different electrical, solar and/or battery powered vehicles and/or stationary power producing units by blending the different technologies in about the same spatial area. This would create more efficient power units and decrease our energy dependence on fossil fuels. By harvesting the renewable energy from all these structures, buildings and/or useful areas, which are in, close proximity to the where the energy is needed, it eliminates the need to redo the failing and outdated massive electric power grid structure. I've heard that this could cost billions to overhaul to deliver the power to its destination needed.

This could also be our nation's 1^{st} line of defense and progress at the same time. We will supply foreign nations' power by approving and protecting the patent. It would also drastically reduce “our carbon footprint” in this world Terrorist threat/s blackouts and power breaks would be greatly reduced in this area of power, because instead of maybe 10 major avenues of power coming into this country, there would be thousands of avenues of power production within our country.

### BRIEF SUMMARY

My idea is to reduce our use of the natural fuels and increase the viability of our alternative power/energies as suggested in the “TITLE” paragraph.

### DETAILED DESCRIPTION

Use all possible and different measuring devices needed for the claims I will present, such as a wind tunnel to measure drag and/or air flow (I don't know the various measuring devices needed, except the wind tunnel, otherwise I would have stated them). Current technologies can be used but are amended to fit circumstances, like generic types of medicine are used instead of the specific concoction itself. I believe this will reduce our dependency on our natural resources and enhance our increased energy available from our renewable resources. AND, I believe the cost of doing these tests and using them, will prove it is a cheaper and wiser thing to do. Also, we would not have to rely on other countries for these energies as we could be harvesting them ourselves.

Each adapted idea would conform to its own area and the appropriate measuring device and/or devices must analyze each area and/or structure for appropriate sizes, numbers of each type of alternative power units to be installed, etc. Any possible adverse weather conditions should be resolved prior to installation and/or retrofitting of the wind, solar and/or water generators. By scientific prediction and laboratory testing and using the best results from the testing for the alternative energies of mostly wind and solar, as well as water, when applicable, it will greatly improve efficiencies. For example, if a wind generator were to be put behind a solar collection system of 6 feet by 6 feet, the blades could extend only to extend no further than the 6-foot width.

Geothermal could add wind and/or solar where possible when possible.

The windmill generator located on the Indian casino land could add a solar panel wrap-around to the tower of the windmill generator thereby generating more electrical power. This extra power should be able to hook directly into the substation of the generator. Reflectors could be placed opposite the sun to gather and direct the solar for added efficiency. Any “wind farms” could do the same thing. Also any extra space could be used for solar panels.

Then I started thinking about other motorized and non-motorized vehicles. Any vehicle that is powered by solar, battery, and/or electric power would enjoy increased power by adding wind turbine/generator as well as other alternative power thereby greatly decreasing the need for more electrical energy stops. A prime example of this motorized alternative energy would be an automobile powered by a battery and/or solar and/or able to be plugged into an electrical outlet. By having a wind tunnel and other tests examine this vehicle having these attributes, a wind tunnel could specifically place a wind turbine(s) and/or solar collectors in strategic locations on the car. This would further enhance the electrical output for this particular vehicle. The automobile could also be charged while parked and/or in a garage by having a stationary generator, which could be hooked up to the vehicle, outside the garage capturing the wind energy.

The placement of the wind generation systems could be on/in and/or under the bumper(s), under the vehicle, the sides and/or under the possibly added solar panels on the roof and/or hood and/or top for the greatest possible power grid for that particular vehicle. A scoop type front, like the old fighter planes had, could be placed where the engine would normally be to generate wind power narrowing to a wind tunnel (funnel-like) that makes electricity. Also the wheels when turning could be used for generating more energy. Commercial vehicles powered by electrical, battery and/or solar could add wind turbines to cut down of fuel need.

All of these added dimensions could possibly eliminate the need for extra power stops,

such as plugging into an electrical outlet, except on rare occasions such as going up a very steep incline. This could be handled by use of a towline, like in ski areas, pulling the vehicles up the steep grade. This towline would be accomplished by having a separate and segregated lane powered by wind and solar power as much as possible.

“Solar farms” could add wind turbines under the solar panel collectors and create rigid but collapsible windmill generators for times when the wind is available but the sun is not.

All river gorges, like the Columbia River, with a goodly wind supply could be harvested by using cable stretched across the river and above the expanse of it.

Rivers with a good water flow, like the Niagara River at the falls, could harvest the energy from this flow with paddles for producing the turbine electricity from the river flow itself and also the falls of the Niagara River.

Bridges could be harvesting wind and solar from above, below, and sides as well as harvesting the power of the water current. This bridge could be retrofitted with solar panels, wind turbines (propeller and water wheel paddles types), road-driven wind generators, and water paddle wheel turbines to harvest available sun, wind, traffic and water flows. The water paddle wheel turbines would be able to float but stationary. If we assume each bridge could harvest all these types of energy and there were numerous bridges, say 1000 bridges, in a river system like the Mississippi River, we could be saving millions of gallons of fossil fuel per year just by using these principles.

Hydroelectric plants could harvest more energy by retrofitting solar and wind. Also, they could use the water-wheel paddle/s to harvest their volumes of water pushed out through their systems. Reusable sources of energy, which have already been used and/or are currently or have been used, include hydroelectric power plants, usually with dams. Yet those to be used could include waterfalls and even flowing water, like Niagara Falls and the Columbia River area. Hydroelectric facilities could help capture spent water plumage as well as dam runoff with water wheels to generate electricity.

Frequently used runways could harvest the wind generated by the air plane traffic using a reducer type of wind turbine, which could handle the 100+ mph winds. A solar only plane could add wind generation to it this plane could add distance, speed and/or carrying capacity. After being in-flight the wind generation only physical restrictions would be when it interferes with the pilot and/or operation of the plane.

Ships, which use battery and/or electrical, could harness the water by using underwater paddles to generate energy as well as using solar and wind capabilities above. Submarines could also harvest the water propulsion by use of water paddles. In the ocean, boats and ships of all sizes could harness not only the wind and solar technologies, but also use the water power to add more power, like a water wheel propels an old gristmill. These could be specifically placed at various locations after ensuring the correct location(s) are presented. This might also include submarines. Alternative energies could be used for motorcycles and possibly even bicycles. Buses and trucks could also be included.

All places, not of the “farm” type, using solar could also use wind turbines under the solar panels to generate more energy. Any and all structures should be useable for wind and/or solar harvesting. We could bury the wind generator blade/s (?) in the road/or have them underneath, above or even to the side of bridges, tunnels, overpasses, etc. Therefore wind power from the road traffic could be harvested using the wind generator system.

When digging holes in the roads to place an underground wind generator system, the spot should be located where there is good speed to justify location, traffic jams are not a regular occurrence, except in tunnels, or there is not enough traffic to justify the location. The Alameda-Oakland tunnel is a prime example. It is an aqueduct connecting these two cities and doesn't have posted speeds over 35 mph, I believe. The tunnel wind from these vehicles could be harvested from the road, sides and ceiling.

Geothermal places might be able to add wind and/or solar and/or paddles to harvest the waterpower, like described elsewhere.

Places, such as homes and businesses, with solar could adapt wind generating capabilities. The wind turbine propellers and/or solar panels attached to buildings for energy harvesting should be kept within the particular building confines. So, maybe after proper evaluations, The Empire State Building has 8 wind turbines (propeller type) placed on the north side, with 100,000 square feet of solar on the south. The east and west sides each have the same square footage of solar with wind turbines behind the solar panels as well as the appropriate coverage of wind and solar on the roof Because of limited fossil fuels creating an energy crunch in this world, we need to really examine our needs and propulsion capabilities. This paper should help find many ways to do this!

Create a new “Supertrailer” to haul our goods, etc. while decreasing the need for fossil fuel by adding an on-board brain (computer), run by solar and wind power, and with all the safety features necessary for highway use. Wheels that can be steered by the computer would replace the landing gears. My biggest target and hardest to correct has been the trailer of the tractor-trailer link. By eliminating the semi of this duo, a trailer could be set free to initiate a lot of new thinking ideas as to almost eliminate the need for the semi.

Start with the landing gears and discard them and in their place put two wheels, that could be steered with appropriate other modifications by the “Supertrailer's” “brains”. Yet there should be available room for the semi to hook up to the Supertrailer if need be. The Supertrailer would also undergo wind tunnel tests to accurately place the wind turbines in conjunction with the solar cells. The Supertrailer would have to have “eyes” or cameras to help it gauge distances, an onboard global positioning system, the whole safety deal with lights (be they headlights, running lights or back up lights, etc.), brake lights, turn signals, etc. and braking power. This could include a need for a semi to hook up to it to haul it up a steep incline, because of lack of necessary power. Dispatch may need to send a semi to haul the Supertrailer to its destination because of time constraints. Its “brain” would turn on the proper turn signals for turning. It would apply the brakes as needed for a safe operation. The “brain” could be easily turned off with proper coding and hook up of the semi would then shut down the “brain”.

The capacities of the wind turbine and solar cells would still harvest electrical power is possible. All of the “eyes” would help aid the “brain” to communicate any problems to dispatch. The “brain” would have to do all the things that a driver has to contend with, such as turning the Supertailer, braking when needed using various lights to let others know its intentions, paying tolls, making emergency stops. The “brain” would also stop at a logical out of the way place to “rest” or let the wind turbine and solar cells build up a sufficient supply of power and communicate with dispatch of any problems encountered.

The power would come from storage batteries located about the middle of the underneath of the “Supertrailer” and would supply power to the rear motors for the rear wheels. When running “empty” like between pick-up points, it should be possible to have rigid, but collapsible, sides and top, that could still deliver electrical output from the wind turbine and solar cells.

Each street light, signal, etc. should have collectors of wind and solar.

All new structures must be able to supply 100% of a normal day's power when built. This should be done as soon as possible. And, all older structures must be able to provide X % of the needed power by date certain (say 50% by 2020). If the structure has not yet started-it must adhere to normal day power guidelines (12 sun hours, x miles per hour winds) with any combinations of alternative types of power to fulfill the guidelines.

Any place could include alternative energy/s as in wind generation systems to harvest trains' and/or subways continuously passing energies on the side's and/or underground and/or possibly roof areas. Processing and manufacturing areas and/or plants with any downward and/or free-falling material, including water, material, etc. could harvest the falling of these items either by the free-falling material itself and/or from any downward sloping belts and/or conveyors. This should only be done if such a thing would not disrupt the processes of the facility or area.

Anything mentioned herein could be used as stated or taken by each item and used separately or in combination with other items. Because there are limited fossil fuels in this world, which creates an energy crunch, we need to really examine our needs and energy capabilities. If the federal government could help subsidize this, it would definitely decrease our dependence on fossil fuels. This paper should help create many ways to do this.

1. Harvesting the numerous alternative energy solutions mentioned by combining, adding, reshaping, modifying, rethinking and/or blending these various energy output devices thereby greatly reducing our dependence on natural fuels such as coal, oil, wood, etc.; that supply our energy needs and are rapidly shrinking.
